(19) United States
(12) Patent Application Publication
(10) Pub. No.: US 2007/0279127 A1
(43) Pub. Date: Dec. 6, 2007

(54) High Linearity Modulation System and Modulation Method

(76) Inventor: Jong-Haeng Lee, Daedeok-gu (KR)

Correspondence Address: Frank Chau, Esq.;F. CHAU & ASSOCIATES, LLC, 130 Woodbury Road, Woodbury, NY, 11797, US

(21) Appl. No.: 11/608,581

(22) Filed: Dec. 8, 2006

(30) Foreign Application Priority Data
Jun. 2, 2006 (KR) 10-2006-0050038

(51) Int. Cl. H03F 3/38

(52) U.S. Cl. 330/10

(57) ABSTRACT

A modulation system and method having a high linearity. The system is a PWM modulator or a class D amplifier and includes an integrator, a low pass filter (LPF), a comparator, and an output circuit. The LPF is located before the comparator. Jitter noise produced by the comparator and/or switching noise of the output circuit are removed by feedback to the input. Thus, the linearity of the modulation system is provided.

### CROSS-REFERENCE TO RELATED PATENT APPLICATIONS

This application claims priority under 35 U.S.C. § 119 to Korean Patent Application No. 10-2006-0050038, filed on Jun. 2, 2006, the disclosure of which is hereby incorporated by reference in its entirety.

### BACKGROUND OF THE INVENTION

1. Technical Field

The present disclosure relates to a modulation system, and more particularly, to a modulation system and method having high linearity.

2. Discussion of the Related Art

Typically, amplifiers are classified into analog amplifiers and digital amplifiers. The analog amplifiers include class A amplifiers, class B amplifiers, and class AB amplifiers. The digital amplifiers include class D amplifiers. Since the analog amplifiers, for example, class A amplifiers, class B amplifiers, and class AB amplifiers, are less efficient than digital amplifiers, for example, class D amplifiers, power loss of analog amplifiers is very high. Thus, a lot of heat is generated in analog amplifiers and the temperature of the analog amplifiers increases when in use.

In the analog amplifier, since a large heat sink or cooling fan is needed to forcibly dissipate the heat generated, the size of the analog amplifier is increased. Also, when the temperature of an audio apparatus including the analog amplifier increases, the analog amplifier may be damaged. Furthermore, in an analog amplifier using a vacuum tube or a transistor, distortion of a signal may be unavoidable as a result of thermal noise due to thermal motion of electrons and the unstable linearity of an amplification device, for example, a vacuum tube or a transistor.

In contrast, the class D amplifier has a high efficiency and is small and light compared to the analog amplifier, thus providing portability. Also, since the power consumed due to heat in the class D amplifier is relatively small, the class D amplifier is widely used.

FIG. 1 is a functional block diagram of a general class D amplifier. Referring to FIG. 1, a class D amplifier 5 includes an input gain stage 10, a PWM modulator 20, and power stages 30 and 40.

An audio signal input to the input gain stage 10 is an analog signal and may be an input signal of an audio apparatus that is commonly used. The input gain stage 10 receives and amplifies the analog signal. The PWM modulator 20 includes a circuit (not shown) in the form of a comparator, and compares the input analog signal with a predetermined reference signal and generates a PWM signal according to the result of the comparison.

For example, when the level of the input analog signal is greater than that of the reference signal, the PWM modulator 20 outputs a high level or “1”. When the level of the input analog signal is less than that of the reference signal, the PWM modulator 20 outputs a low level or “0”. That is, the PWM modulator 20 generates a PWM signal based on the input analog signal and the reference signal.

Each of the power stages 30 and 40 receives the PWM signal output from the PWM modulator 20, buffers the signal, and outputs the buffered signal to an inductive load, for example, a speaker. The class D amplifier 5 is a full bridge type amplifier having two power stages 30 and 40. The full bridge type amplifier may generate high-powered output. Meanwhile, a class D amplifier using one only power stage is a half bridge type amplifier.

FIG. 2 is a block diagram of a conventional PWM modulator having a ramp generator. As shown in FIG. 2, a PWM modulator 20 has a ramp generator 23 generating ramp signals 36 and 38. Examples of ramp generators may be found in U.S. Pat. No. 6,262,632. Comparators 41 and 42 receive the ramp signals 36 and 38 (respectively) generated from the ramp generator 23 and integrated signals output from integrators 24 and 26 (respectively) and generate PWM signals based on the respective integrated signals and the respective ramp signals 36 and 38.

Since the PWM modulator 20 has the ramp generator 23 shown in FIG. 2, the structure of the PWM modulator 20 is complicated and difficult to manufacture. Also, since switching noise of each of the output terminals 28 and 30 can be included in the output signals of the integrators 24 and 26, distortion may be generated in the output signals of the integrators 24 and 26.

FIG. 3 is a block diagram showing a conventional self-oscillation PWM modulator. Examples of self-oscillation PWM modulators may be found in U.S. Pat. No. 6,362,702. As shown in FIG. 3, the self-oscillation PWM modulator does not include a ramp generator unlike the PWM modulator shown in FIG. 2. Since switching noise of an output terminal 6 of the self-oscillation PWM modulator can be introduced to an integrator 12, an output signal Vb of the integrator 12 can be distorted.

### SUMMARY OF THE INVENTION

Embodiments of the present invention provide a modulation system and method having high linearity.

According to an exemplary embodiment of the present invention, a system comprises a first integrator integrating a first input signal and a first feedback signal including a first PWM switching noise. The first integrator generates a first integral signal. A first LPF removes the first PWM switching noise from the first integral signal and outputs a signal removed of the first PWM switching noise. A first comparator compares a reference signal with an output signal of the first LPF and generates a first PWM signal corresponding to the comparison result. A first output circuit buffers the first PWM signal and generates the first feedback signal.

The system may further comprise a second integrator integrating a second input signal and a second feedback signal including a second PWM switching noise. A second LPF removes the second PWM switching noise from the second integral signal and outputs a signal removed of the second PWM switching noise. A second comparator compares the reference signal with an output signal of the second LPF and generates a second PWM signal corresponding to the comparison result. A second output circuit buffers the second PWM signal and generates the second feedback signal.

The system may further comprise a first resistor to allow the first feedback signal to feedback to the first integrator and a second resistor to allow the second feedback signal to feedback to the second integrator. The system may further comprise a signal generator to generate a sawtooth wave or triangular wave as the reference signal. The system may further comprise an inductive load connected to the first output circuit or to the second output circuit.

The first integrator may comprise a first amplifier including a first input terminal to receive the first input signal, a second input terminal to receive a predetermined bias voltage, and an output terminal to output the first integral signal. A first capacitor may be connected between the first input terminal and the output terminal. The first feedback signal is input to the first input terminal of the first integrator.

The first integrator may comprise a first amplifier including a first input terminal to receive the first input signal, a second input terminal to receive a predetermined bias voltage, and a first output terminal to output the first integral signal. A first capacitor may be connected between the first input terminal and the first output terminal. The second integrator may comprise a second amplifier including a first input terminal to receive the second input signal, a second input terminal to receive the bias voltage, and a second output terminal to output the second integral signal. A second capacitor may be connected between the first input terminal and the second output terminal. The first feedback signal is input to the first input terminal of the first integrator and the second feedback signal is input to the first input terminal of the second integrator.

The first integrator may comprise a first amplifier including a first input terminal to receive the first feedback signal, a second input terminal to receive the first input signal, and an output terminal to output the first integral signal. A first capacitor may be connected between the first input terminal and the output terminal.

The first integrator may comprise a first amplifier including a first input terminal to receive the first feedback signal, a second input terminal to receive the first input signal, and a first output terminal to output the first integral signal. A first capacitor may be connected between the first input terminal of the first amplifier and the first output terminal. The second integrator may comprise a second amplifier including a first input terminal to receive the second feedback signal, a second input terminal to receive the second input signal, and a second output terminal to output the second integral signal. A second capacitor may be connected between the first input terminal of the second amplifier and the second output terminal. The first input signal and the second input signal may be differential signals. The system may be a PWM modulator or a class D amplifier.

According to an exemplary embodiment of the present invention, a modulation method comprises integrating a first input signal and a first feedback signal including a first PWM switching noise and generating a first integral signal. Low pass filtering is applied to the first integral signal to remove the first PWM switching noise from the first integral signal. A first signal removed of the first PWM switching noise is output. A reference signal is compared with the first signal and a first PWM signal corresponding to the comparison result is generated. The first PWM signal is buffered and the first feedback signal is generated.

The method may further comprise integrating a second input signal and a second feedback signal including a second PWM switching noise and generating a second integral signal. Low pass filtering may be applied to the second integral signal to remove the second PWM switching noise from the second integral signal and a second signal removed of the second PWM switching noise is output. The reference signal is compared with the second signal and a second PWM signal corresponding to a comparison result is generated. The second PWM signal is buffered and the second feedback signal is generated.

### BRIEF DESCRIPTION OF THE DRAWINGS

The above and other features of exemplary embodiments of the present invention will become more apparent by describing the exemplary embodiments in detail with reference to the attached drawings in which:

FIG. 1 is a functional block diagram of a general class D amplifier;

FIG. 2 is a block diagram of a PWM modulator having a ramp generator;

FIG. 3 is a block diagram of a self-oscillation PWM modulator.

FIG. 4 is a functional block diagram of a modulation system according to exemplary embodiments of the present invention;

FIG. 5 is a functional block diagram of a modulation system according to exemplary embodiments of the present invention;

FIG. 6A is a pair of graphs showing the waveforms of an output voltage and a low pass filter of the modulation system when the output voltage of the modulation system is saturated;

FIG. 6B is a pair of waveform diagrams obtained by magnifying the first section of FIG. 6A;

FIG. 6C is a pair of waveform diagrams obtained by magnifying the second section of FIG. 6A; and

FIG. 6D is a pair of waveform diagrams obtained by magnifying the third second of FIG. 6A.

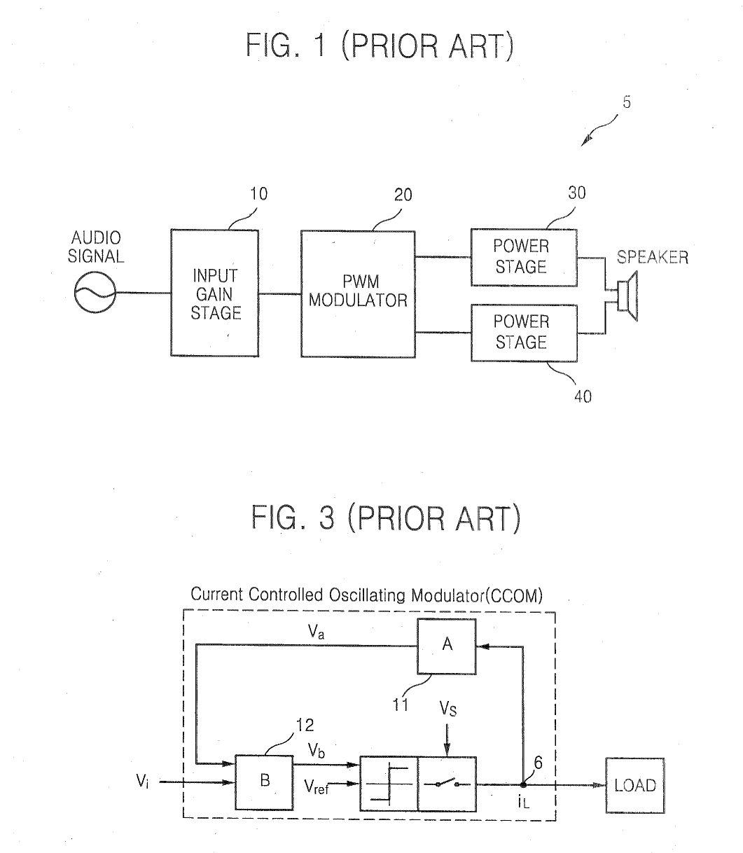

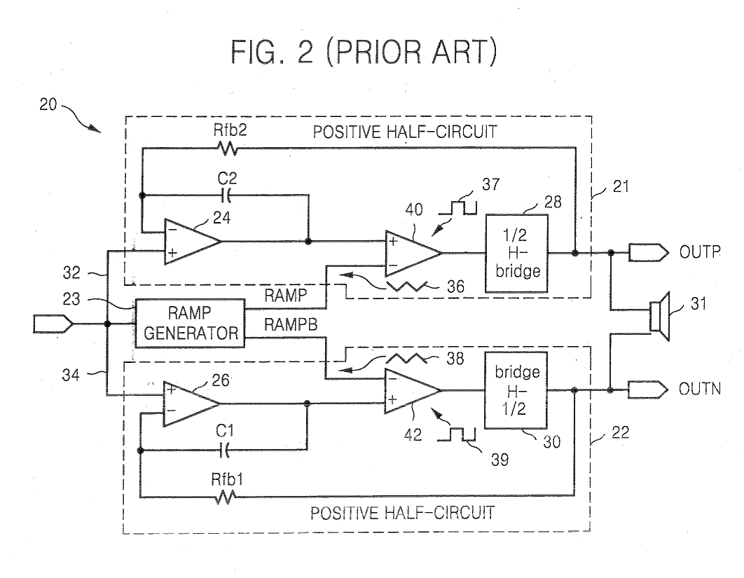

### DETAILED DESCRIPTION OF THE EXEMPLARY EMBODIMENTS

The attached drawings are referred to in order to gain a sufficient understanding of exemplary embodiments of the present invention.

Exemplary embodiments of the present invention are described in detail herein with reference to the attached drawings. Like reference numerals in the drawings denote like elements.

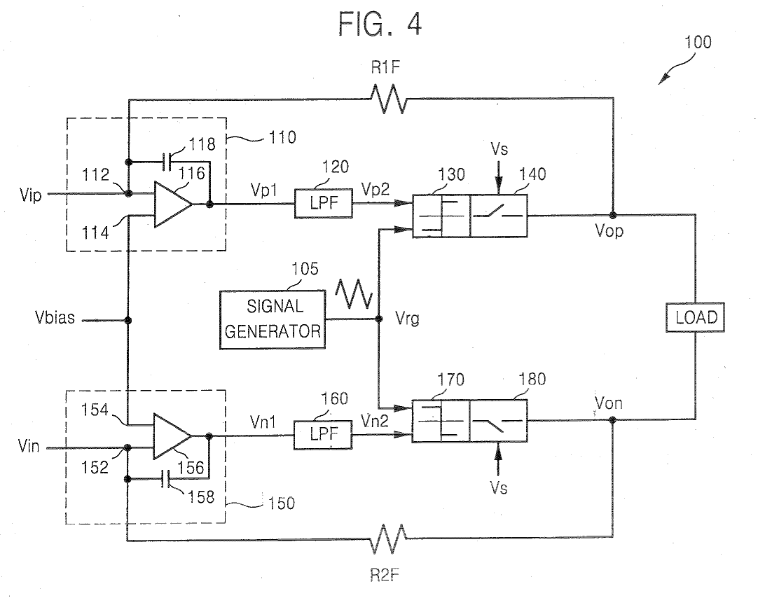

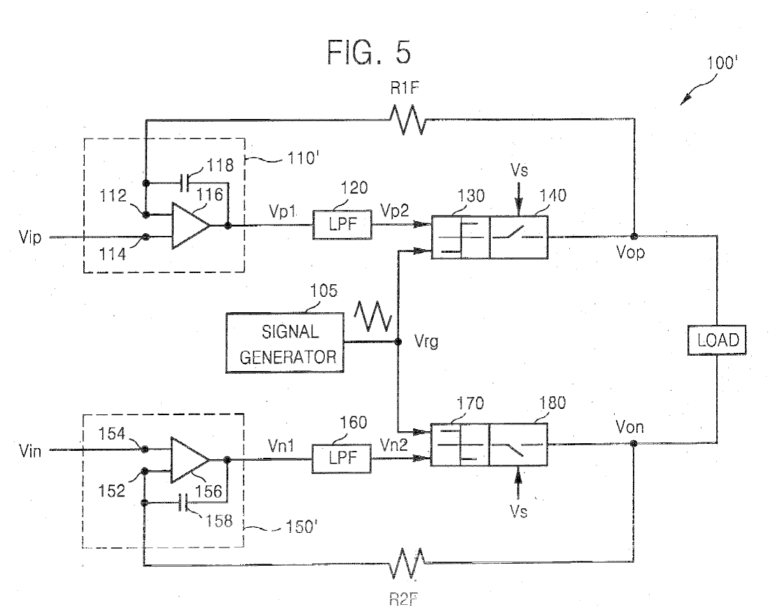

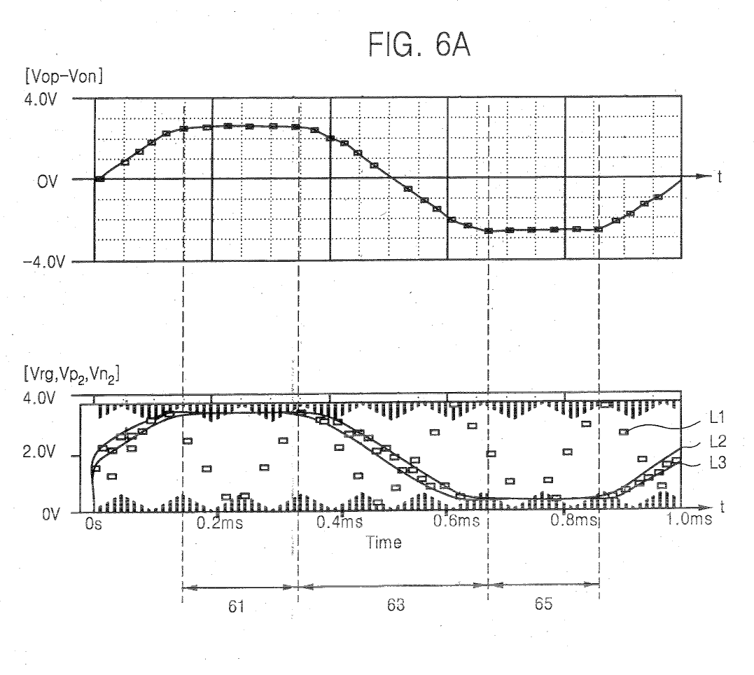

FIG. 4 is a functional block diagram of a modulation system according to exemplary embodiments of the present invention. FIG. 5 is a functional block diagram of a modulation system according to an exemplary embodiment of the present invention.

Referring to FIGS. 4 and 5, modulation systems 100 (100′ in FIG. 5) capable of reducing electromagnetic interference (EMI) include a signal generator 105, a first integrate 110 (110′ in FIG. 5), a first low pass filter (LPF) 120, a first comparator 130, a first output circuit 140, a second integrator 150 (150′ in FIG. 5), a second LPF 160, a second comparator 170, and a second output circuit 180. The first integrator 110 (110′ in FIG. 5), the first LPF 120, the first comparator 130, the first output circuit 140, and a feedback resistor (R1F) can constitute a self-oscillation PWM modulator. The modulation system 100 (100′ in FIG. 5) having a high linearity can be embodied by a PWM modulator or a class D amplifier.

The signal generator 105 provides a predetermined reference signal Vrg to the first and second comparators 130 and 170. The reference signal Vrg may be a triangular wave, a sawtooth wave, or DC.

The first integrator 110 (110′ in FIG. 5) receives a first input signal Vip and a first feedback signal Vop including a first PWM switching noise and generates a first integral signal Vp1 based on the received signals Vip and Vop. The second integrator 150 (150′ in FIG. 5) receives a second input signal Vin and a second feedback signal Von including a second PWM switching noise and generates a second integral signal Vn1 based on the received signals Vin and Von. The first and second input signals Vip and Vin may be differential signals or complementary signals, but the present invention is not limited thereto.

The first integrator 110 of FIG. 4 includes an amplifier 116 and a first capacitor 118. The amplifier 116 includes a first input terminal 112 to receive the first input signal Vip, a second input terminal 114 to receive a predetermined bias voltage Vbias, and an output terminal to output the first integral signal Vp1. The first capacitor 118 is connected between the input terminal 112 of the amplifier 116 and the output terminal of the amplifier 116. Also, the first input terminal 112 receives the first feedback signal Vop including the first PWM switching noise through the first resistor R1F.

The second integrator 150 includes an amplifier 156 and a second comparator 158. The amplifier 156 includes a first input terminal 152 to receive the second input signal Vin, a second input terminal 154 to receive the bias voltage Vbias, and an output terminal to output the second integral signal Vn1. The second capacitor 158 is connected between the input terminal 152 of the amplifier 156 and the output terminal of the amplifier 156. Also, the first input terminal 152 receives the second feedback signal Von including the second PWM switching noise through the second resistor R2F.

As shown in FIG. 5, the first integrator 110′ includes the amplifier 116 and the first capacitor 118. The amplifier 116 includes the first input terminal 112 to receive the first feedback signal Vop including the first PWM switching noise, the second input terminal 114 to receive the input signal Vip, and the output terminal to output the first integral signal Vp1. The first capacitor 118 is connected between the first input terminal 112 of the amplifier 116 and the output terminal of the amplifier 116.

The second integrator 150′ includes the amplifier 156 and the second capacitor 158. The amplifier 156 includes the first input terminal 152 to receive the second feedback signal Von including the second PWM switching noise, the second input terminal 154 to receive the input signal Vin, and the output terminal to output the second integral signal Vn1. The second capacitor 158 is connected between the first input terminal 152 of the amplifier 156 and the output terminal of the amplifier 156.

When each of the first and second resistors R1F and R2F is replaced by an inverter (not shown), each of the first and second feedback signals Vop and Von of the modulation system, 100 in FIG. 4 and 100′ in FIG. 5, can be input through the inverter corresponding to each of signals.

The first LPF 120 removes the first PWM switching noise from the first integral signal Vp1 and outputs a signal Vp2 removed of the first PWM switching noise. The second LPF 160 removes the second PWM switching noise from the second integral signal Vn1 and outputs a signal Vn2 removed of the second PWM switching noise.

High frequency noise such as jitter noise by each of the first and second comparators 130 and 170 and/or switching noise by each of the first and second output circuits 140 and 180 is input to each of the first and second integrators, 110 in FIG. 4 and 110′ in FIG. 5 and 150 in FIG. 4 and 150′ in FIG. 5.

When the cut-off frequency of each of the first and second LPFs 120 and 160 is set to be low, each of the first and second LPFs 120 and 160 can remove the high frequency noise. Thus, the modulation system 100, in FIG. 4 and 100′ in FIG. 5, according to present embodiments has high linearity.

The first comparator 130 receives the output signal Vp2 of the first LPF 120 and the reference signal Vrg generated by the signal generator 105 and generates the first PWM signal by comparing the received signals. The second comparator 170 receives the output signal Vn2 of the second LPF 160 and the reference signal Vrg generated by the signal generator 105 and generates the second PWM signal by comparing the received signals.

For example, when the level of the output signal Vp2 of the first LPF 120 is greater than that of the reference signal Vrg, the first comparator 130 outputs a high level of “1”. When the level of the output signal Vp2 of the first LPF 120 is less than that of the reference signal Vrg, the first comparator 130 outputs a low level or “0”. Thus, the first comparator 130 pulse width modulates the output signal Vp2 of the first LPF 120 based on the reference signal Vrg. The PWM method of the second comparator 170 is similar to that of the first comparator 130.

The first output circuit 140 buffers the first PWM signal and generates the first feedback signal Vop. The second output circuit 180 buffers the second PWM signal and generates the second feedback signal Von. Both of the first and second output circuits 140 and 180 can be embodied by a plurality of MOS transistors.

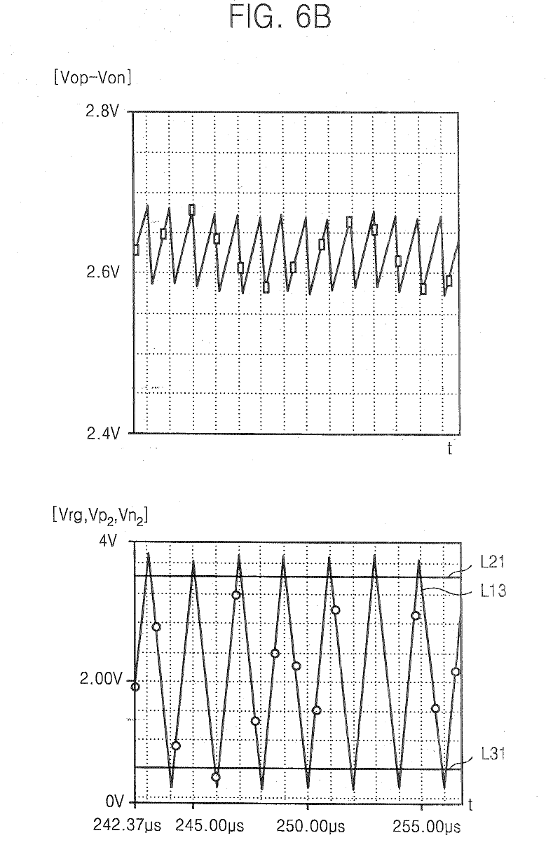

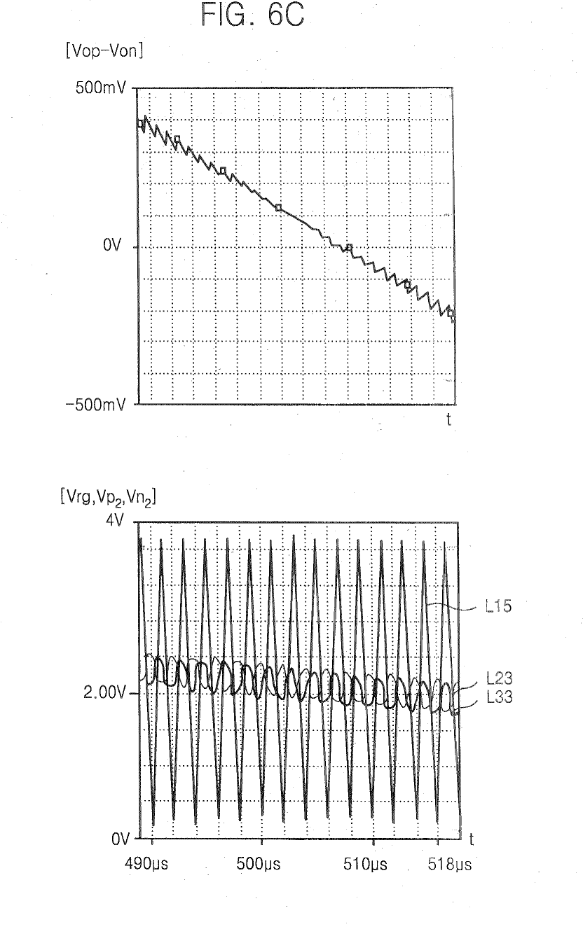

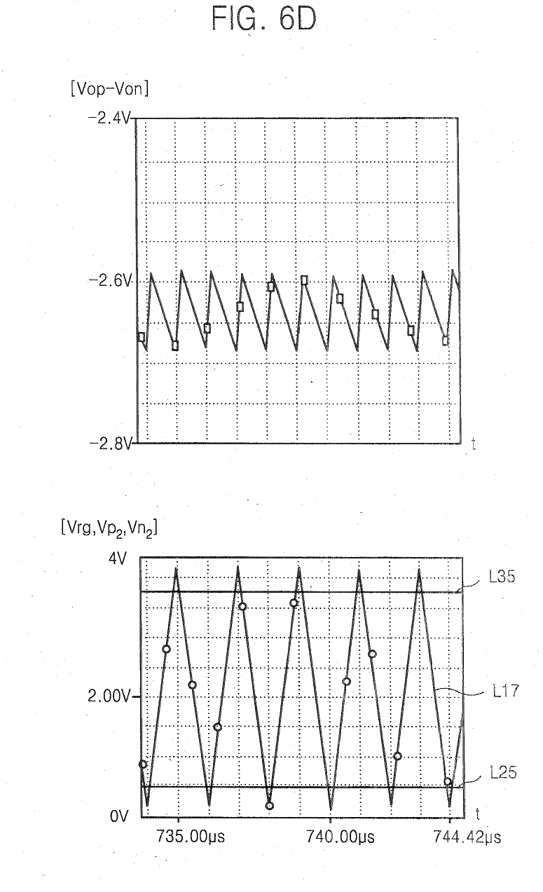

FIG. 6A is a set of graphs showing the waveform of an output voltage and a low pass filter of the modulation system when the output voltage of the modulation system is saturated. FIGS. 6B through 6D are waveform diagrams respectively obtained by magnifying first, second, and third sections 61, 63, and 65 of FIG. 6A. Referring to FIGS. 4 through 6D, in the first section 61 shown in FIG. 6A, an output voltage (Vop-Von) corresponding to the output voltages Vop and Von of the modulation system 100 in FIG. 4 and 100′ in FIG. 5 is saturated by a predetermined power voltage supplied to each of the comparators 130 and 170.

The output signals Vp2 and Vn2 of the first and second LPFs 120 and 160 are respectively signals obtained by modulating the input signals Vip and Vin. The output signals Vp2 and Vn2 of the first and second LPFs 120 and 160 are PWM modulated based on the reference signal Vrg (L1, L13, L15, and L17) of the signal generator 105. Like the waveform shown in FIG. 6B, the output voltage Vop-Von of the modulation system 100 in FIG. 4 and 100′ in FIG. 5 is saturated at a power voltage, for example, about 2.6 V, supplied to each of the first and second comparators 130 and 170.

In the first section 61 of FIG. 6A, the output voltage Vop-Von of the modulation system 100 in FIG. 4 and 100′ in FIG. 5 is saturated by the power voltage. It can be seen that the waveform L21 of FIG. 6B of the output signal Vp2 of the first LPF 120 in the first section 61 is not modulated by the saturation due to the power voltage and is output as a saturation voltage L21 of FIG. 6B of about 3.5 V. Also, it can be seen that the waveform L31 of the output signal Vn2 of the second LPF 160 in the first section 61 is not modulated by the saturation due to the power voltage and is output as a saturation voltage L31 of about 0.5 V.

In the second section 63 of FIG. 6A, the output voltage Vop-Von of the modulation system 100 in FIG. 4 and 100′ in FIG. 5 is the output voltage Vop-Von before saturation by the power voltage. It can be seen that the output signal Vp2 of the first LPF 120 in the second section 63 is normally modulated like the waveform L23 of FIG. 6C. Also, it can be seen that the output signal Vn2 of the second LPF 160 in the second section 63 is normally modulated like the waveform L33 of FIG. 6C.

In the third section 65 of FIG. 6A, the output voltage Vop-Von of the modulation system 100 in FIG. 4 and 100′ in FIG. 5 is saturated by the power voltage. It can be seen that the waveform L25 of FIG. 6D of the output signal Vp2 of the first LPF 120 in the third section 65 is not modulated by the saturation due to the power voltage and is output as a saturation voltage L25 of about 0.5 V. Also, it can be seen that the waveform L35 of the output signal Vn2 of the second LPF 160 in the third section 65 is not modulated by the saturation due to the power voltage and is output as a saturation voltage L35 of about 3.5 V.

That is, it can be seen that the waveform L21, L23, and L25 of the output signal Vp2 of the first LPF 120 and the waveforms L31, L33, and L35 of the output signal Vn2 of the second LPF 160 of the modulation system 100 in FIG. 4 and 100′ in FIG. 5 are not modulated when saturated by the power voltage of each of the first and second comparators 130 and 170 are not modulated and maintain the constant voltage levels L21, L25, L31, and L35.

As described above, since the LPF is located before the comparator, a high linearity is provided. The method of providing a high linearity according to at least one embodiment of the present invention can be achieved by removing the jitter noise by the comparator and the switching noise of the output circuit.

What is claimed is:

1. A system comprising:
a first integrator generating a first integral signal by integrating a first input signal and a first feedback signal including a first PWM switching noise;
a first LPF removing the first PWM switching noise from the first integral signal;
a first comparator comparing a reference signal with an output signal of the first LPF and generating a first PWM signal corresponding to a comparison result; and
a first output circuit buffering the first PWM signal and generating the first feedback signal.

2. The system of claim 1, further comprising a first resistor to allow the first feedback signal to feedback to the first integrator.

3. The system of claim 1, further comprising a signal generator to generate a sawtooth wave or triangular wave as the reference signal.

4. The system of claim 1, further comprising an inductive load connected to the first output circuit.

5. The system of claim 1, further comprising:
a second integrator integrating a second input signal and a second feedback signal including a second PWM switching noise;
a second LPF removing the second PWM switching noise from the second integral signal;
a second comparator comparing the reference signal with an output signal of the second LPF and generating a second PWM signal corresponding to a comparison result; and
a second output circuit buffering the second PWM signal and generating the second feedback signal.

6. The system of claim 5, further comprising a second resistor to allow the second feedback signal to feedback to the second integrator.

7. The system of claim 5, further comprising a signal generator to generate a sawtooth wave or triangular wave as the reference signal.

8. The system of claim 5, further comprising an inductive load connected to the first output circuit or the second output circuit.

9. The system of claim 1, wherein the first integrator comprises:
a first amplifier including a first input terminal to receive the first input signal, a second input terminal to receive a predetermined bias voltage, and an output terminal to output the first integral signal; and
a first capacitor connected between the first input terminal and the output terminal,
wherein the first feedback signal is input to the first input terminal of the first integrator.

10. The system of claim 5, wherein the first integrator comprises:
a first amplifier including a first input terminal to receive the first input signal, a second input terminal to receive a predetermined bias voltage, and a first output terminal to output the first integral signal; and
a first capacitor connected between the first input terminal and the first output terminal, and
the second integrator comprises:
a second amplifier including a first input terminal to receive the second input signal, a second input terminal to receive the bias voltage, and a second output terminal to output the second integral signals; and
a second capacitor connected between the first input terminal and the second output terminal, and
wherein the first feedback signal is input to the first input terminal of the first integrator and the second feedback signal is input to the first input terminal of the second integrator.

11. The system of claim 1, wherein the first integrator comprises:
a first amplifier including a first input terminal to receive the first feedback signal, a second input terminal to receive the first input signal, and an output terminal to output the first integral signal; and
a first capacitor connected between the first input terminal and the output terminal.

12. The system of claim 5, wherein the first integrator comprises:
a first amplifier including a first input terminal to receive the first feedback signal, a second input terminal to receive the first input signal, and a first output terminal to output the first integral signal; and
a first capacitor connected between the first input terminal of the first amplifier and the first output terminal, and
the second integrator comprises:
a second amplifier including a first input terminal to receive the second feedback signal, a second input terminal to receive the second input signal, and a second output terminal to output the second integral signal; and
a second capacitor connected between the first input terminal of the second amplifier and the second output terminal.

13. The system of claim 1, wherein the first input signal and the second input signal are different signals.

14. The system of claim 1, being a PWM modulator or a class D amplifier.

15. The system of claim 5, being a PWM modulator or a class D amplifier.

16. A modulation method comprising:
generating a first integral signal by integrating a first input signal and a first feedback signal including a first PWM switching noise;
low pass filtering the first integral signal to remove the first PWM switching noise from the first integral signal;
comparing a reference signal with the first signal removed of the first PWM switching noise and generating a first PWM signal corresponding to a comparison result; and
buffering the first PWM signal and generating the first feedback signal.

17. The method of claim 16, further comprising:
generating a second integral signal by integrating a second input signal and a second feedback signal including a second PWM switching noise;
low pass filtering the second integral signal to remove the second PWM switching noise from the second integral signal;
comparing the reference signal with the second signal removed of the second PWM switching noise and generating a second PWM signal corresponding to a comparison result; and
buffering the second PWM signal and generating the second feedback signal.
